(19) United States
(12) Patent Application Publication
(10) Pub. No.: US 2013/0228911 A1
(43) Pub. Date: Sep. 5, 2013

(54) LOW-PROFILE MICROELECTRONIC PACKAGE, METHOD OF MANUFACTURING SAME, AND ELECTRONIC ASSEMBLY CONTAINING SAME

(71) Applicants: Mathew J. Manusharow, Phoenix, AZ (US); Ravi K. Nalla, San Jose, CA (US)

(72) Inventors: Mathew J. Manusharow, Phoenix, AZ (US); Ravi K. Nalla, San Jose, CA (US)

(21) Appl. No.: 13/848,237

(22) Filed: Mar. 21, 2013

Related U.S. Application Data
(62) Division of application No. 12/959,515, filed on Dec. 3, 2010, now abandoned.

(51) Int. Cl. H01L 23/00

(52) U.S. Cl. CPC H01L 23/564
USPC 257/690

(57) ABSTRACT

A low-profile microelectronic package includes a die (110) (having a first surface (111) and a second surface (112)) and a package substrate (120). The substrate includes an electrically insulating layer (121) that forms a first side (126) of the substrate, an electrically conductive layer (122) connected to the die, and a protective layer (123) over the conductive layer that forms a second side (127) of the substrate. The first surface of the die is located at the first side of the substrate. The insulating layer has a plurality of pads (130) formed therein. The package further includes an array of interconnect structures (140) located at the first side of the substrate. Each interconnect structure in the array of interconnect structures has a first end (141) and a second end (142), and the first end is connected to one of the pads.

### CLAIM OF PRIORITY

This application is a divisional of U.S. patent application Ser. No. 12/959,515, now abandoned, which was filed on Dec. 3, 2010.

### FIELD OF THE INVENTION

The disclosed embodiments of the invention relate generally to microelectronic devices, and relate more particularly to low profile packaging for microelectronic devices.

### BACKGROUND OF THE INVENTION

Microelectronic devices such as dies for computing applications and the like are housed in packages that, among other functions, enclose and protect the die or other device and also allow the device to be electrically connected to, for example, a printed circuit board or a similar structure. The long-standing trend toward size reduction in microelectronics operates for packaging just as for the packaged components, and this trend is especially pronounced for devices intended for mobile solutions. More specifically, low overall package height, sometimes referred to as z-height, is increasingly becoming a key requirement, both in mobile and in other market segments.

### BRIEF DESCRIPTION OF THE DRAWINGS

The disclosed embodiments will be better understood from a reading of the following detailed description, taken in conjunction with the accompanying figures in the drawings in which:

FIGS. 1-4 are cross-sectional views of a low-profile microelectronic package according to embodiments of the invention;

FIG. 5 is a cross-sectional view of a microelectronic package that enables a POP architecture according to an embodiment of the invention;

FIGS. 6 and 7 are, respectively, an exploded perspective view and a cross-sectional view of an electronic assembly according to an embodiment of the invention;

FIG. 8 is a cross-sectional view of an electronic assembly according to another embodiment of the invention;

FIG. 9 is a flowchart illustrating a method of manufacturing a package for a microelectronic device according to an embodiment of the invention; and

FIGS. 10-16 are cross-sectional views of a portion of a microelectronic package at various stages in its manufacturing process according to an embodiment of the invention.

For simplicity and clarity of illustration, the drawing figures illustrate the general manner of construction, and descriptions and details of well-known features and techniques may be omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Certain figures may be shown in an idealized fashion in order to aid understanding, such as when structures are shown having straight lines, sharp angles, and parallel planes that under real-world conditions would be less symmetric and orderly. The same reference numerals in different figures denote the same elements, while similar reference numerals may, but do not necessarily, denote similar elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise,” “include,” “have,” and any variations thereof, are intended to cover a non-exclusive inclusion, such that a process, method, article, or apparatus that comprises a list of elements is not necessarily limited to those elements, but may include other elements not expressly listed or inherent to such process, method, article, or apparatus.

The terms “left,” “right,” “front,” “back,” “top,” “bottom,” “over,” “under,” and the like in the description and in the claims, if any, are used for descriptive purposes and not necessarily for describing permanent relative positions unless otherwise indicated either specifically or by context. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “in one embodiment” herein do not necessarily all refer to the same embodiment.

### DETAILED DESCRIPTION OF THE DRAWINGS

In one embodiment of the invention, a low-profile microelectronic package comprises a microelectronic die having a first surface and an opposing second surface and further comprises a package substrate built up around at least a portion of the microelectronic die. The package substrate comprises an electrically insulating layer that forms a first side of the package substrate, further comprises an electrically conductive layer electrically connected to the microelectronic die, and still further comprises a protective layer over the electrically conductive layer that forms a second side of the package substrate. The first surface of the microelectronic die is located at the first side of the package substrate. The electrically insulating layer has a plurality of pads formed therein. The low-profile microelectronic package further comprises an array of electrically conductive interconnect structures located at the first side of the package substrate. Each individual interconnect structure in the array of electrically conductive interconnect structures has a first end and an opposing second end, and the first end is connected to one of the plurality of pads.

It was mentioned above that low package heights are increasingly important for various market segments, including the mobility segment. Embodiments of the invention address that need with an inverted package configuration made using bumpless build-up layer (BBUL) technology that provides for a package height that is significantly less than is possible with existing solutions. In particular embodiments, as will be discussed in detail below, the die is routed out to ball grid array (BGA) pads on the same side of the package as the die, and the die is placed in a space defined by BGA balls attached to the BGA pads. Embodiments of the invention work well for dies having relatively few bumps and relatively low power requirements, where passive cooling would be sufficient, while other embodiments work well with, and may be optimized for, dies having relatively large numbers of bumps and relatively high power requirements (and that may need more robust thermal management solutions).

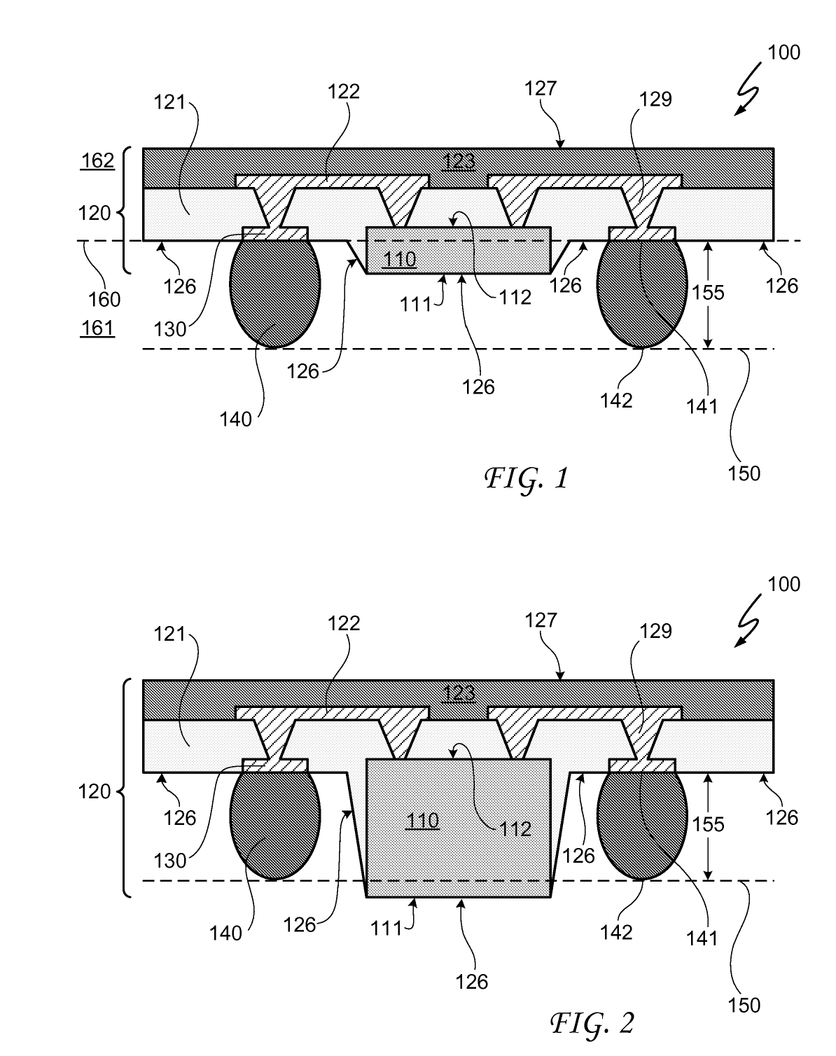

Referring now to the drawings, FIGS. 1-4 are cross-sectional views of a low-profile microelectronic package 100 according to embodiments of the invention. As illustrated in FIG. 1, microelectronic package 100 comprises a microelectronic die 110 having a surface 111 and an opposing surface 112. A package substrate 120 is built up around at least a portion of microelectronic die 110 and comprises an electrically insulating layer 121, an electrically conductive layer 122 electrically connected to microelectronic die 110 (e.g., using vias 129), and a protective layer 123 over electrically conductive layer 122. Only one electrically conductive layer is shown, but package 100 could in certain embodiments comprise multiple electrically conductive layers formed and interconnected according to known processes. Protective layer 123 would then be formed over the uppermost/final metal layer. As an example, these electrically conductive layers could be copper layers or other metal layers, perhaps formed using semi-additive process (SAP) techniques or the like. The protective layer protects the underlying conductive layers by preventing electrical shorting, preventing corrosion of the copper or other materials making up the conductive layers, and protects those materials from the elements. As an example, protective layer 123 can comprise a solder resist or the like.

Electrically insulating layer 121, a lower surface of which forms a side 126 of package substrate 120, has a plurality of pads 130 formed therein. A side 127 of package substrate 120—located opposite side 126—is formed by un upper surface of protective layer 123. Surface 111 of microelectronic die 110 is located at side 126 of the package substrate.

Microelectronic package 100 further comprises an array of electrically conductive interconnect structures 140 located at side 126 of package substrate 120. These can be ball grid array (BGA) balls, meaning the pads 130 can be BGA pads. Alternatively, the interconnect structures can be solder grid array (SGA) balls. Each individual interconnect structure in the array has an end 141 and an opposing end 142, and end 141 is connected to one of pads 130. Ends 142 of interconnect structures 140 define a plane 150 located at a distance 155 from pads 130. Surface 111 of die 110 is located at a second distance from pads 130. In one embodiment, this second distance is less than distance 155, while in another embodiment the second distance is greater than distance 155. The first of these two embodiments may be similar to what is shown in FIG. 1. Because in this first embodiment the die is located within a region or space defined by interconnect structures 140, rather than being attached above protective layer 123, as in conventional architectures, this configuration enables a low-profile package that is a desired outcome of embodiments of the present invention.

The latter of the two embodiments mentioned above—that is, the embodiment where the second distance is greater than distance 155, or, in other words, where surface 111 of die 110 extends below plane 150—may be accomplished by increasing the thickness of the die, in a manner such as that shown in FIG. 2. Alternatively, it may be accomplished with a die having a thickness similar to that shown in FIG. 1 by manipulating the thicknesses of the various package substrate layers and/or by manipulating the level at which such a (relatively thin) die is located within the package substrate. This latter embodiment, though it has a larger z-height than does the embodiment of FIG. 1, offers a potential advantage in terms of thermal management capabilities, as will be further discussed below.

The package substrate in a BBUL environment is generally considered to include the entire package other than the die itself. As known to those of ordinary skill in the art, BBUL technology involves dies that are embedded within—rather than attached to a surface of—a package substrate. Thus, in BBUL technology, build-up layers are built up around the die, thereby obviating the need for flip-chip bumps or other external die attach mechanisms.

Another feature of BBUL technology is that the depth to which the die is embedded may be adjusted. In terms of embodiments of the present invention, that ability to adjust the die embedding depth (accomplished in ways that will be discussed below), means that microelectronic die 110 may be located at various places within package substrate 120 with respect to some particular reference point. For example, one may use a plane defined by pads 130 as a reference point by which to define the location of microelectronic die 110. Thus, referring again to FIG. 1, pads 130 may be used to define a plane 160 within electrically insulating layer 121. Then, as shown, interconnect structures 140 are on a side 161 of plane 160 and protective layer 123 is on the other side of the plane, i.e., on a side 162.

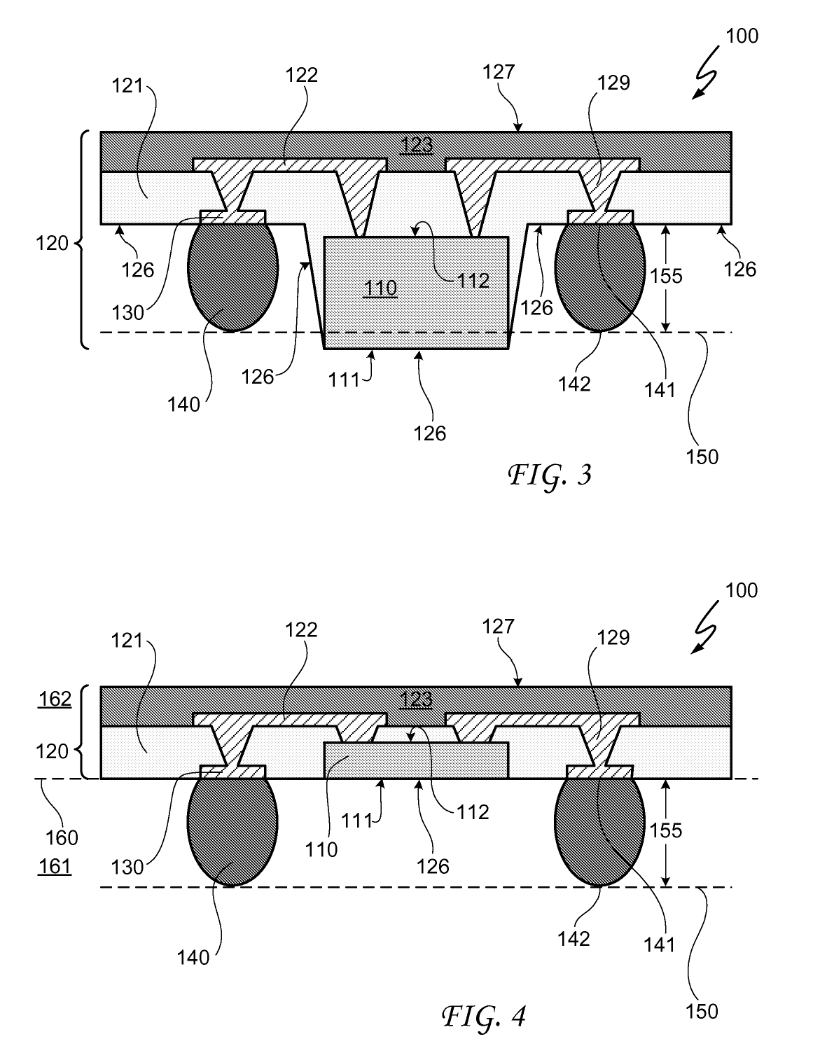

Having defined a frame of reference, various embodiments of microelectronic package 100 may now be set forth as follows. In a first embodiment, surface 111 of microelectronic die 110 lies on side 161 of plane 160. Examples of this embodiment, referred to herein as “partially embedded” embodiments, are shown in both FIG. 1 and FIG. 2. In a second embodiment, surface 111 and surface 112 of microelectronic die 110 both lie on side 161 of plane 160. An example of this embodiment, referred to herein as a “fully outside” or “un-embedded” embodiment, is illustrated in FIG. 3. In a third embodiment, surface 111 of microelectronic die 110 (along with surface 112) is on side 162 of plane 160 (or perhaps lies in plane 160 itself). An example of this embodiment, referred to herein as a “fully embedded” configuration, is illustrated in FIG. 4.

Any or all of the foregoing embodiments may offer advantages in terms of a low-profile microelectronic package. Additional advantages may be realized by enabling package-on-package (POP) configurations. POP architecture is an increasingly important trend in certain product categories—including mobile devices—in part because of the space savings and manufacturing advantages that it provides. Embodiments of the present invention enable POP architecture, as discussed below.

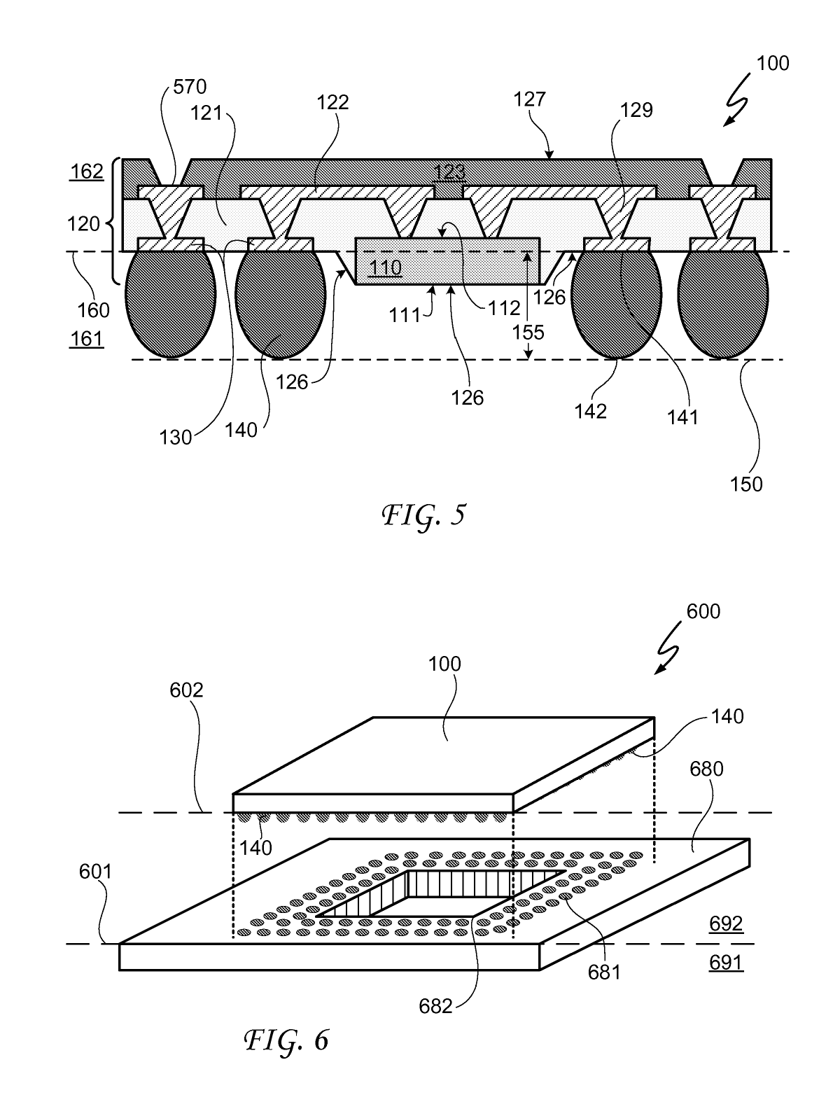

FIG. 5 is a cross-sectional view of microelectronic package 100 in an embodiment that enables a POP architecture according to an embodiment of the invention. As illustrated in FIG. 5, protective layer 123 may be opened up (e.g., using standard lithography techniques) so as to expose package-on-package pads 570. These POP pads are shown connecting directly to BGA pads 130, but could alternatively connect to die 110 using routing within the substrate. Pads 570 may be used as attachment points for an upper package such as a memory module or the like (not shown) that is to be stacked on microelectronic package 100 in a POP arrangement.

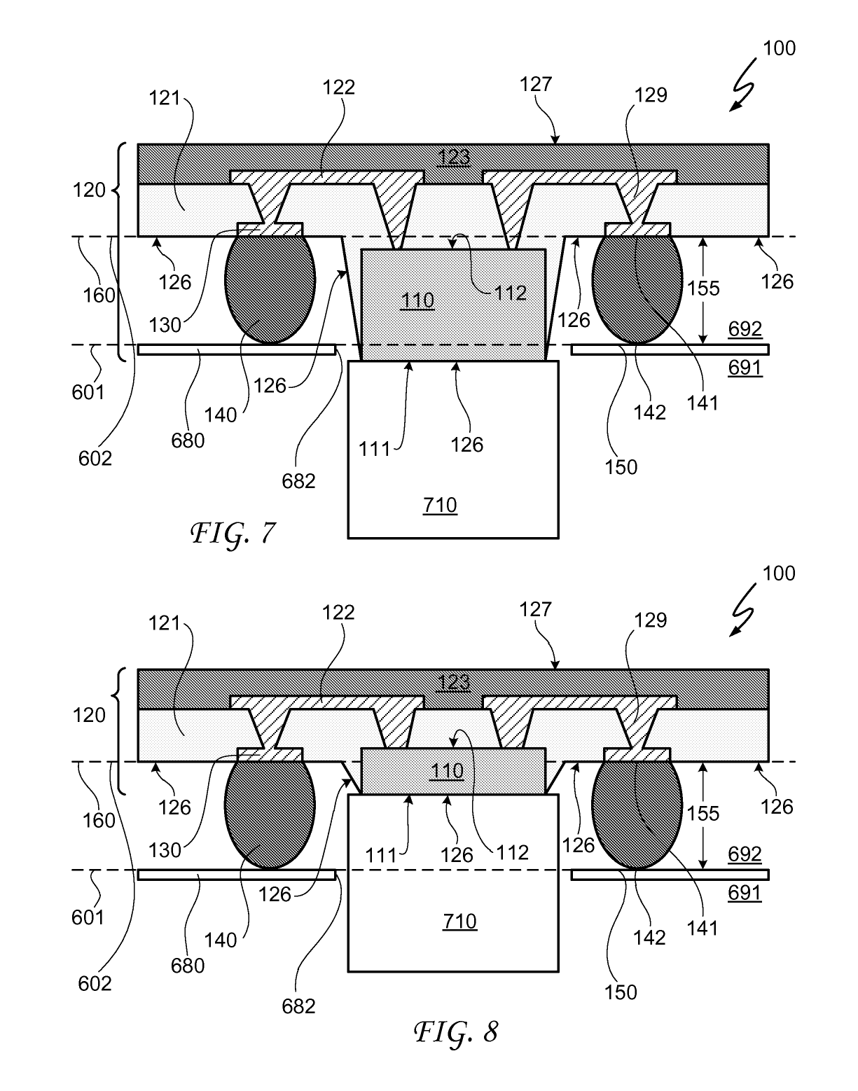

FIG. 6 is an exploded perspective view and FIG. 7 is a cross-sectional view of an electronic assembly 600 according to an embodiment of the invention. Electronic assembly 600 includes low-profile microelectronic package 100. In FIG. 6, package 100 is represented by a generic block from which most of the details of the previous figures have been omitted (though portions of interconnect structures 140 may be seen). Electronic assembly 600 also comprises a board 680 to which package 100 is attached. (For clarity, package 100 is shown suspended above board 680, with dashed lines indicating the location of its attached position.) The attachment may be made—in accordance with well-known techniques—by bringing interconnect structures 140 and corresponding pads 681 (located on board 680) into contact with each other and reflowing interconnect structures 140 in order to form electrical connections between package and board.

In the illustrated embodiment, board 680 has an opening 682. This opening extends completely through the board and thus allows objects to pass through the middle of the board (i.e., through the opening) from one side of the board to the other. A practical advantage of this configuration, further discussed in the following paragraphs, is that for high-power (or other) applications a thermal management structure, a heat sink for example, may be brought into contact with, or otherwise help dissipate heat from, microelectronic die 110. This is not possible with configurations in which board 680 lacks an opening therein because those configurations do not allow sufficient space for thermal management structures to be placed in contact with the die.

Board 680 defines a plane 601 of electronic assembly 600 and pads 130 in electrically insulating layer 121 define a plane 602 of the electronic assembly. Note that pads 130 and layer 121, which are depicted in FIGS. 1-5, are not shown in FIG. 6. It should also be noted that plane 602 is at least roughly equivalent to plane 160 that was introduced above in a slightly different context. Similarly, plane 601 is at least roughly equivalent to plane 150 that was also introduced above in a slightly different context. As illustrated, plane 601 has a side 691 and an opposing side 692, with plane 602 being located on side 692 of plane 601.

In one embodiment, surface 111 of microelectronic die 110 is located on side 691 of plane 601 such that it protrudes through opening 682 in board 680. An example of this embodiment is shown in FIG. 7. Also shown in FIG. 7 is a cooling device 710 attached to package 100 such that the cooling device is adjacent to side 111 of die 110. Cooling device 710 can be a heat sink, a heat spreader, a microchannel, or any other suitable thermal management structure.

In another embodiment, surface 111 of microelectronic die 110 is located on side 692 of plane 601. In this embodiment, depicted in FIG. 8, die 110 does not protrude through opening 682. Instead, cooling device 710, or at least a portion thereof, also lies on side 692 of plane 601, having been introduced through opening 682 from side 691 after board 680 and package 100 are coupled to each other. (Alternatively, cooling device 710 may be attached to package 100 prior to the attachment of package and board.)

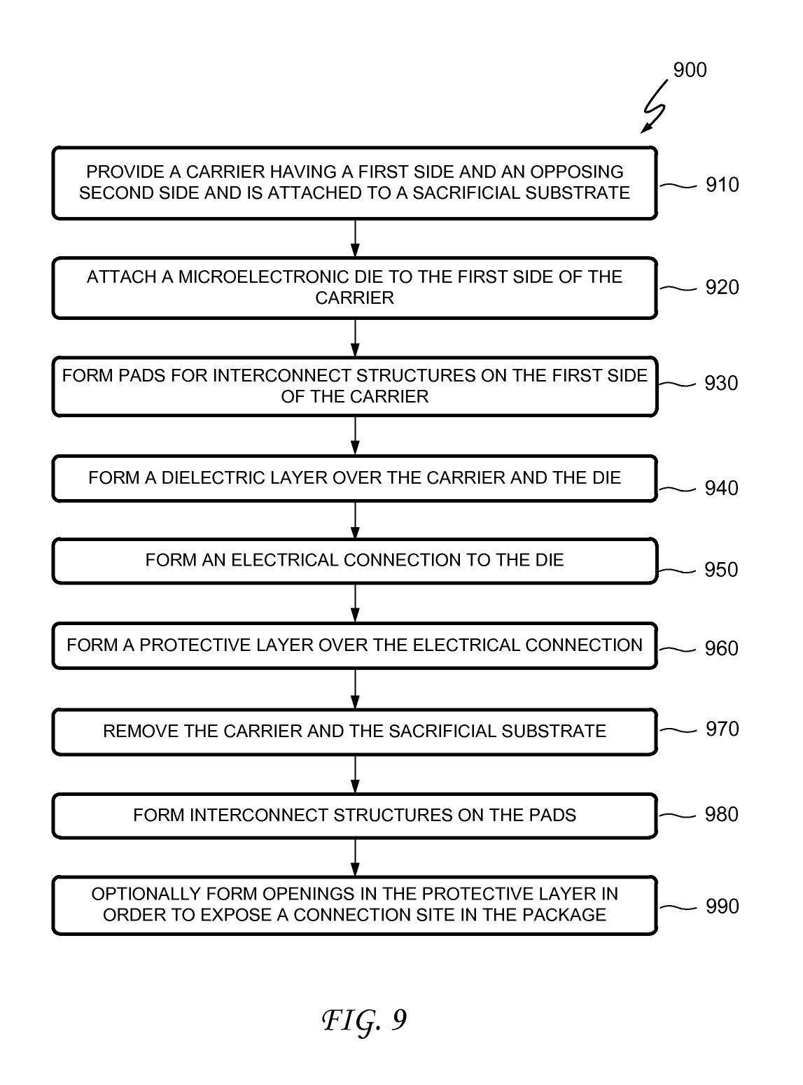

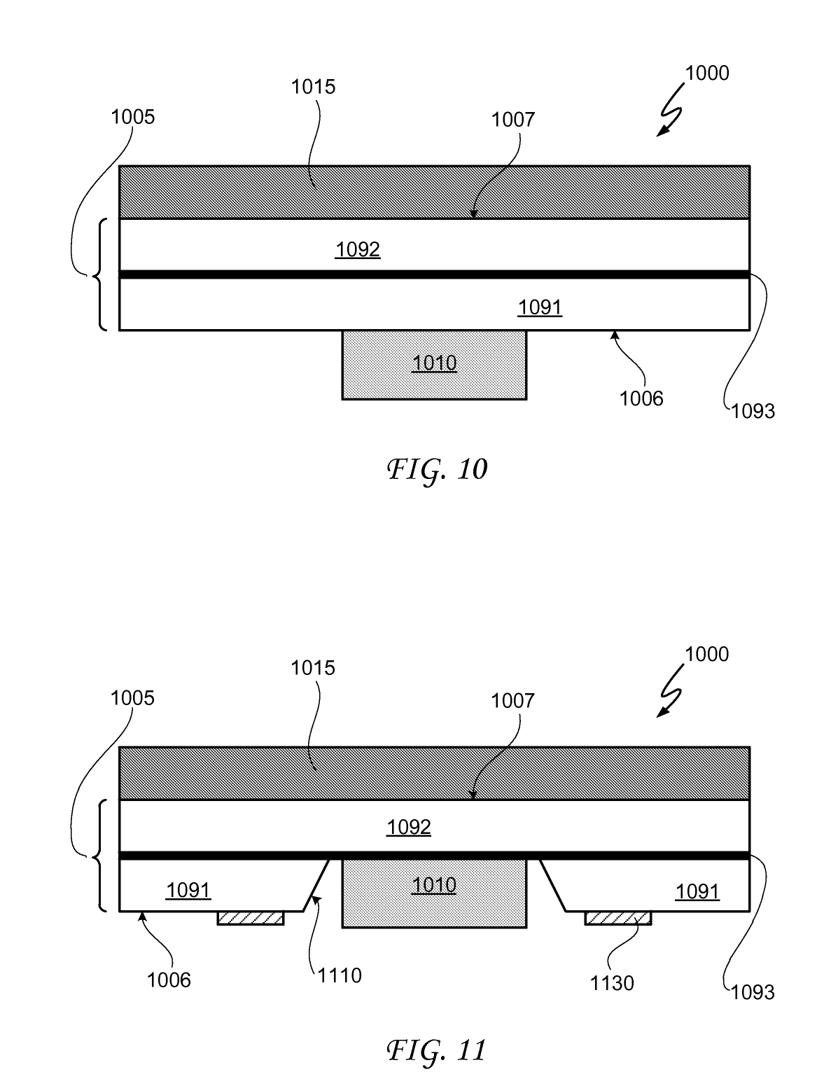

FIG. 9 is a flowchart illustrating a method 900 of manufacturing a package for a microelectronic device according to an embodiment of the invention. As an example, method 900 may result in the formation of a microelectronic package that is similar to microelectronic package 100 that is first shown in FIG. 1. Either wafer-level or panel-level processing may be used. Method 900 is further illustrated in FIGS. 10-16, all of which are cross-sectional views of a package 1000 at various stages in its manufacturing process according to embodiments of the invention. It should be noted that although the figures show one-sided construction, in at least some embodiments manufacturing will be done in parallel in a back-to-back, double-sided manner. A depiction of such double-sided parallel processing would include what is shown in FIGS. 10-13 plus the mirror image of what is shown there, with a sacrificial core in between the two sides.

A step 910 of method 900 is to provide a carrier having a first side and an opposing second side and is attached to a sacrificial substrate. As an example, the carrier can be similar to a carrier 1005 that is shown in FIG. 10. The first side of the carrier can be similar to a side 1006 of carrier 1005, and the second side of the carrier can be similar to a side 1007 of carrier 1005. In one embodiment, the carrier can be a copper foil or the like. As another example, the sacrificial substrate can be similar to a substrate 1015 that is also illustrated in FIG. 10 and that may take the form of a peelable core. This sacrificial substrate allows the part to be handled during manufacturing.

In one embodiment, step 910 comprises providing a multi-layer copper foil or the like comprising a first layer of copper (or another suitable material), a second layer of copper (or another suitable material), and a barrier layer in between the first and second layers. As an example, the first layer, the second layer, and the barrier layer can be similar to, respectively, a layer 1091, a layer 1092, and a layer 1093, all of which are shown in FIG. 10. The barrier layer can comprise, for example, nickel or another suitable metal, build-up film, solder resist, dry film resist, or any other material capable of acting as an etch stop and of defining a flat surface on which to place the die.

A step 920 of method 900 is to attach a microelectronic die to the first side of the carrier. As an example, the microelectronic die can be similar to microelectronic die 110 that is first shown in FIG. 1. As another example, the microelectronic die can be similar to a microelectronic die 1010 that is shown in FIG. 10. In the embodiment illustrated in FIG. 10, step 920 comprises attaching the die to an unaltered carrier 1005, that is, to a carrier that generally has the form shown for it in FIG. 10. In another embodiment, step 920 comprises forming a cavity in the carrier and attaching the microelectronic die in the cavity. This embodiment is illustrated in FIG. 11, where package 1000 is shown to have a cavity 1110 formed in side 1006 of carrier 1005 and where die 1010 is located in cavity 1110.

As an example, the cavity may be formed by patterning a dry film layer that has been laminated onto the carrier according to techniques that are known in the art. The patterning may include an etching procedure, also known in the art, that etches all the way through the first layer of the carrier and stops on the barrier layer. (A thickness of the first layer thus dictates, at least in part, a depth of the cavity.) As another example, the die may be attached in the cavity by dispensing an adhesive onto the carrier, by pre-attaching an adhesive die backside film (DBF) onto the back of the die prior to its placement in the cavity, or by using similar techniques. If desired, the DBF can be provided with metallic particles (e.g., copper or silver) in order to enhance thermal dissipation.

A depth to which the die is embedded within the package substrate depends at least in part on a thickness of the first copper layer and on a corresponding depth of the cavity therein. (This concept will be more fully explored later in this discussion after the relevant structural details have been introduced.) Thus, in one embodiment method 900 further comprises selecting a thickness of the first copper layer based upon at least one of a thickness of the microelectronic die and a depth to which the microelectronic die is to be embedded within the package.

A step 930 of method 900 is to form pads for interconnect structures on the first side of the carrier. As an example, the pads can be similar to pads 130 that are first shown in FIG. 1. As another example, the pads can be similar to pads 1130 that are shown in FIG. 11. The pads, which may in some embodiments comprise copper, may be provided with a desired surface finish (not shown). In one embodiment, a gold-based surface finish may be used.

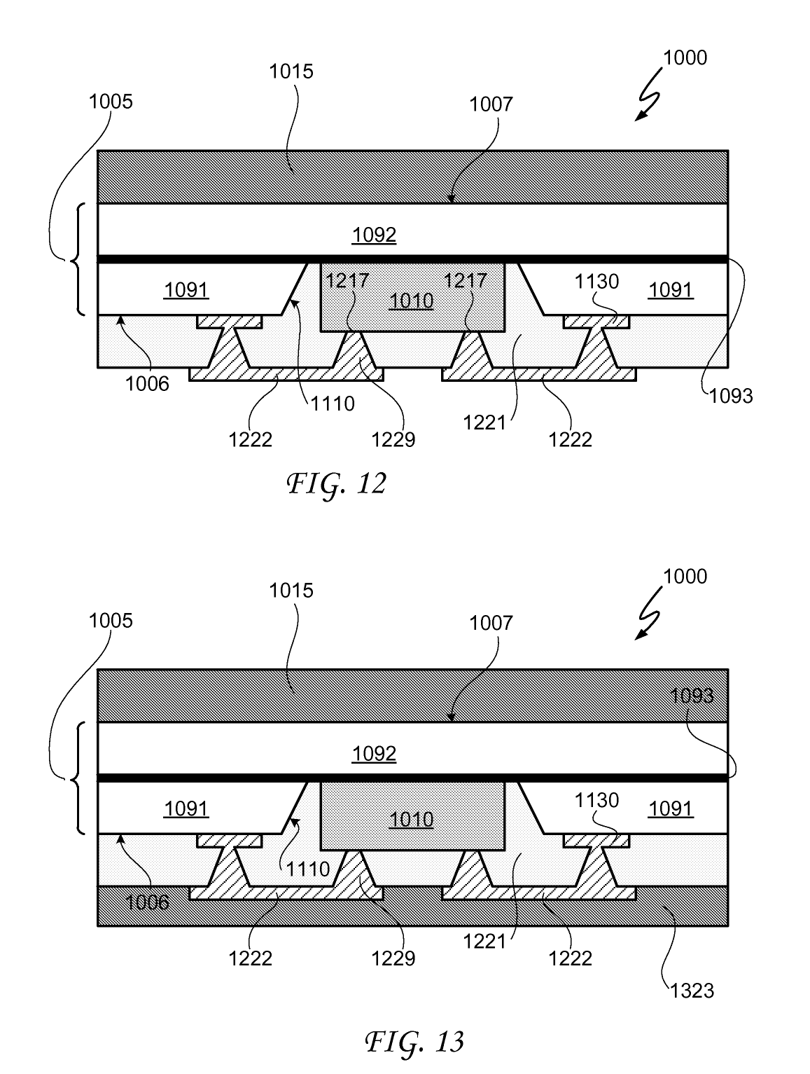

A step 940 of method 900 is to form a dielectric layer over the carrier and the microelectronic die. As an example, the dielectric layer can be similar to electrically insulating layer 121 that is first shown in FIG. 1. As another example, the dielectric layer can be similar to a dielectric layer 1221 that is shown in FIG. 12. In one embodiment, a dielectric film may be laminated (e.g., on an entire panel) providing a level plane for the rest of the build-up process. The carrier may be roughened prior to lamination in order to aid with adhesion to the dielectric film.

A step 950 of method 900 is to form an electrical connection to the microelectronic die. In one embodiment, step 950 comprises forming vias landing on electrically conductive structures of the microelectronic die, plating the vias with an electrically conductive material, and forming a metal layer in the dielectric layer and electrically connecting it to the electrically conductive material in the vias. With reference to FIG. 12, these features are visible as vias 1229, electrically conductive structures 1217, and a metal layer 1222. In a particular embodiment, SAP techniques are used to plate the vias landing on the die pads and the first metal layer of the substrate portion of the package. Additional layers (not shown) may also be used to route out the die bumps to the BGA pads. The use of such additional layers may be dictated by the number of input/output (I/O) bumps needed, by power delivery considerations, and/or by geometrical constraints or other factors.

A step 960 of method 900 is to form a protective layer over the electrical connection. As an example, the protective layer can be similar to protective layer 123 that is first shown in FIG. 1. As another example, the protective layer can be similar to a protective layer 1323 that is shown in FIG. 13.

It was mentioned above that a depth to which the die is embedded within the package substrate depends at least in part on a thickness of the first copper layer and on a corresponding depth of the cavity therein. For example, if no cavity is formed and the die is therefore positioned as shown in FIG. 10, the resulting structure (after package manufacturing has been completed) is what is referred to herein as a fully embedded configuration, meaning the die is located within the dielectric layer roughly between the interconnect structure pads and the protective layer. An example of this configuration was shown in FIG. 4. Accordingly, fully embedding the microelectronic die in the package means, at least in one embodiment, attaching the microelectronic die to a carrier without a cavity. On the other hand, if a cavity is formed and the die is therefore positioned as shown in FIG. 11, the resulting structure (after package manufacturing has been completed) is what is referred to herein as a partially embedded configuration, meaning one surface of the die is located on one side of the interconnect structure pads and another surface of the die is located on another side of the interconnect structure pads. Examples of this configuration were shown in FIGS. 1 and 2. Accordingly, partially embedding the microelectronic die in the package means, at least in one embodiment, attaching the microelectronic die to a carrier inside of a cavity having a particular depth. If the depth is great enough and/or depending on a thickness of the die—see FIG. 3—the result may be what is referred to herein as an un-embedded configuration.

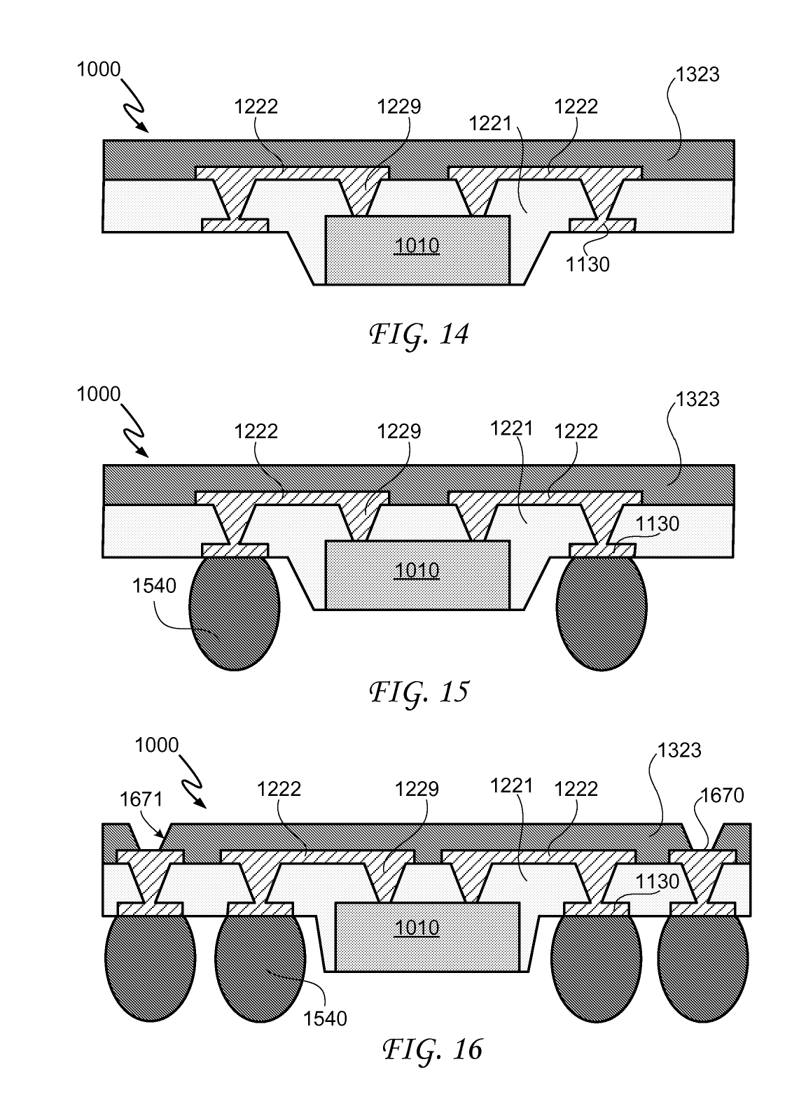

A step 970 of method 900 is to remove the carrier and the sacrificial substrate. As an example, the removal may be accomplished using an etching process. After this is done, and the remaining structure is inverted, package 1000 appears as shown in FIG. 14.

A step 980 of method 900 is to form interconnect structures on the pads. This may be done using standard ball attach processes. As an example, the interconnect structures can be similar to interconnect structures 140 that are first shown in FIG. 1. As another example, the interconnect structures can be similar to interconnect structures 1540 that are shown in FIG. 15.

An optional step 990 of method 900 is to form openings in the protective layer in order to expose a connection site in the package. The connection site may be used, for example, as a connection point to which may be attached an additional microelectronic package in a POP architecture or the like. As an example, the connection site can be similar to package-on-package pads 570 that are shown in FIG. 5. As another example, the connection site can be similar to a connection site 1670 that is shown in FIG. 16. The openings in the protective layer can be similar to, for example, openings 1671 that are also shown in FIG. 16.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that the microelectronic package and the related structures and methods discussed herein may be implemented in a variety of embodiments, and that the foregoing discussion of certain of these embodiments does not necessarily represent a complete description of all possible embodiments.

Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1. An electronic assembly comprising:
a low-profile microelectronic package comprising:
a microelectronic die having a first surface and an opposing second surface;
a package substrate built up around at least a portion of the microelectronic die, the package substrate comprising a plurality of pads; and
a board attached to the low-profile microelectronic package,
wherein:
the board has an opening therein;
the board defines a first plane of the electronic assembly and the plurality of pads define a second plane of the electronic assembly;
the first plane has a first side and an opposing second side, with the second plane being located on the second side of the first plane; and
the first surface of the microelectronic die is located on the first side of the first plane such that it protrudes through the opening in the board.

2. The electronic assembly of claim 1 further comprising:
a cooling device attached to the low-profile microelectronic package such that it is adjacent to the first side of the microelectronic die.

3. The electronic assembly of claim 1 further comprising:
an electrically insulating layer that forms a first side of the package substrate, the electrically insulating layer containing the plurality of pads, wherein the first surface of the die is located at the first side of the package substrate.

4. The electronic assembly of claim 3 further comprising:
an electrically conductive layer electrically connected to the microelectronic die and located at least partially within the electrically insulating layer.

5. The electronic assembly of claim 4 further comprising:
a protective layer over the electrically conductive layer, the protective layer forming a second side of the package substrate.

6. The electronic assembly of claim 5 further comprising:
package-on-package pads exposed in the protective layer.

7. The electronic assembly of claim 5 further comprising:
an array of electrically conductive interconnect structures located at the first side of the package substrate, wherein each individual interconnect structure in the array of electrically conductive interconnect structures has a first end and an opposing second end, and wherein the first end is connected to one of the plurality of pads, and wherein the board is attached to the low-profile microelectronic package using the array of electrically conductive interconnect structures.

8. The electronic assembly of claim 7 wherein:
the electrically conductive interconnect structures are either BGA balls or SGA balls.
